(19) United States
(12) Patent Application Publication
(10) Pub. No.: US 2007/0047282 A1
(43) Pub. Date: Mar. 1, 2007

(54) Method and apparatus for implementing power saving for content addressable memory

(75) Inventors: Derick Gardner Behrends, Rochester, MN (US); Peter Thomas Freiburger, Rochester, MN (US); Ryan Charles Kivimagi, Chatfield, MN (US); Daniel Mark Nelson, Rochester, MN (US)

Correspondence Address: IBM CORPORATION;ROCHESTER IP LAW DEPT 917, 3605 HIGHWAY 52 N, ROCHESTER, MN, 55901-7829, US

(73) Assignee: International Business Machines Corporation, Armonk, NY (US)

(21) Appl. No.: 11/216,385

(22) Filed: Aug. 31, 2005

(51) Int. Cl. G11C 15/00

(52) U.S. Cl. 365/49

(57) ABSTRACT

A method and apparatus are provided for implementing power saving in a content addressable memory (CAM). A compare array is matched against a key and if a match occurs then logic coupled to the compare array generates a hit signal. A data array includes precharge circuitry and data output latches to capture the data output. A clock gate coupled to the logic provides clock signals to the output latches and precharge circuitry of the data array when a hit occurs. When a hit does not occur, the clock signals are gated off to the output latches and precharge circuitry of the data array.

### FIELD OF THE INVENTION

The present invention relates generally to the data processing field, and more particularly, relates to a method and apparatus for implementing power saving in a content addressable memory (CAM).

### DESCRIPTION OF THE RELATED ART

A content addressable memory (CAM) is known for many diverse uses. For example, many known microprocessor systems use content addressable memories (CAMs) for address translation. Also, for example, in many known microprocessor systems, a respective content addressable memory (CAM) is associated with each of a plurality of primary data cache memories.

Referring to FIG. 1, there is shown a conventional content addressable memory (CAM) that generally contains a compare array and a data array. The compare array is matched against a key and if a match occurs then a hit signal is generated, for example, the hit signal goes high, and a wordline is generated. The wordline is used to access the data array and the data output latches of the data array capture this output.

If a match does not occur then the hit signal will go low and all of the output latches of the array will clock and load precharge. This consumes a large amount of power with each CAM cycle whether or not a hit has occurred.

Current microprocessor designs require the use of low power techniques. CAMs are notorious for large power consumption. Any circuit that could reduce CAM power usage would be valuable.

A need exists for an effective mechanism for implementing power saving in a content addressable memory (CAM).

### SUMMARY OF THE INVENTION

Principal aspects of the present invention are to provide a method and apparatus for implementing power saving in a content addressable memory (CAM). Other important aspects of the present invention are to provide such a method and apparatus for implementing power saving in a content addressable memory (CAM) substantially without negative effect and that overcome many of the disadvantages of prior art arrangements.

In brief, a method and apparatus are provided for implementing power saving in a content addressable memory (CAM). A compare array is matched against a key and if a match occurs then logic coupled to the compare array generates a hit signal. A data array includes precharge circuitry and data output latches to capture the data output. A clock gate coupled to the logic provides clock signals to the output latches and precharge circuitry of the data array when a hit occurs. Otherwise, when a hit does not occur, the clock signals are gated off by the clock gate to the output latches and precharge circuitry of the data array.

In accordance with features of the invention, when the CAM is accessed and a hit does not occur, the data array remains in an inactive state. In the inactive state of the data array, none of the output latches switch, and the precharge circuitry stays on and does not switch, so that power savings are achieved.

### BRIEF DESCRIPTION OF THE DRAWINGS

The present invention together with the above and other objects and advantages may best be understood from the following detailed description of the preferred embodiments of the invention illustrated in the drawings, wherein:

FIG. 1 illustrates a conventional content addressable memory (CAM); and

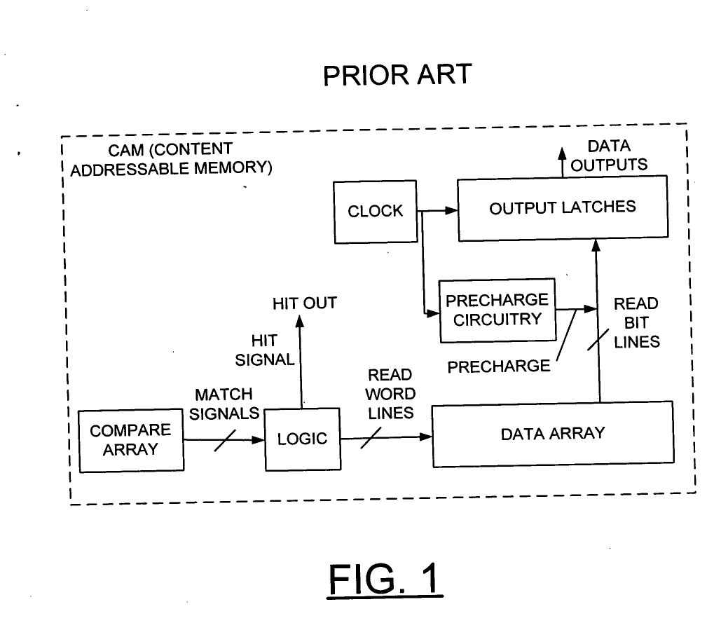

FIG. 2 illustrates a content addressable memory (CAM) for implementing power saving in accordance with the preferred embodiment.

### DETAILED DESCRIPTION OF THE PREFERRED EMBODIMENT

In accordance with features of the preferred embodiment, a new method of using the hit signal is provided to gate off the clock signals feeding the output latches on the data array as well as the precharge circuitry providing precharge signals to the read bitlines of a dynamic read data array for implementing power saving in a content addressable memory (CAM). In CAM arrays typically the read array is much wider than the compare array, which means considerable power savings advantageously is achieved with the preferred embodiment.

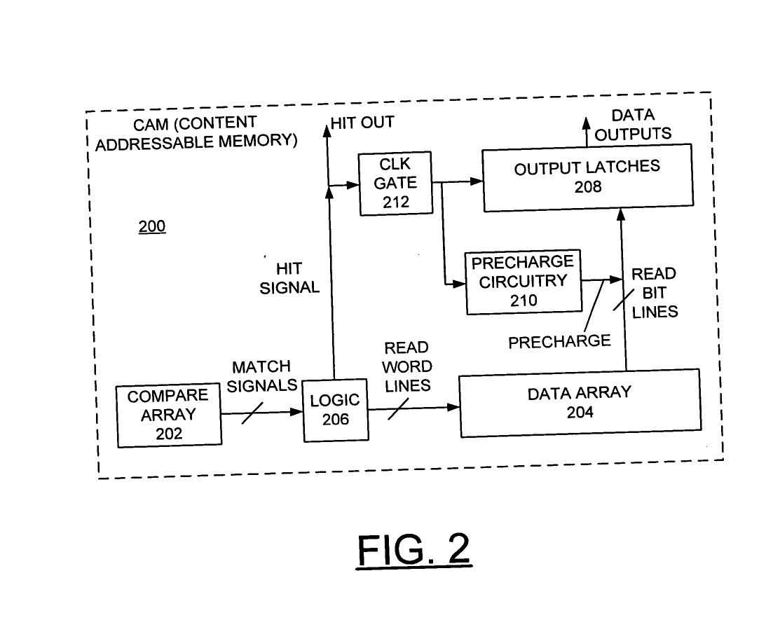

Having reference now to the drawings, in FIG. 2, there is shown a content addressable memory (CAM) for implementing power saving generally designated by the reference character 200 in accordance with the preferred embodiment. CAM 200 includes a compare array 202, and a data array 204. A logic circuit 206 coupled to the compare array 202 generates a hit signal responsive to a match when the compare array is matched against a key, for example, the hit signal goes high, and logic circuit 206 generates a wordline. The wordline is used to access the data array 202.

The data array 202 of CAM 200 includes a plurality of data output latches 208 to capture the data output. The data array 202 of CAM 200 includes a precharge circuitry 210. Precharge circuitry 210 provides precharge signals to the read bitlines of the dynamic read data array 202.

A clock gate 212 in accordance with the preferred embodiment is coupled to the data output latches 208 and the precharge circuitry 210. The hit signal output of logic 206 is applied to the clock gate 212. The clock gate 212 applies clock signals to the output latches 208 and the precharge circuitry 210 when a hit occurs.

In accordance with features of the preferred embodiment, if a match does not occur then the hit signal will go low and the clock gate 212 is used to gate off the clocks feeding the output latches 208 and precharge circuitry 210 in the data array 202. Thus when the CAM 200 is accessed and no hit occurs, the data array 202 stays in an inactive state, meaning none of the output latches 208 switch, and the precharge circuitry 210 stays on and does not switch.

CAM 200 is illustrated in simplified form sufficient for understanding the present invention. It should be understood that the present invention is not limited to the illustrated arrangement of CAM 200. For example, the clock gate 212 in accordance with features of the preferred embodiment can be provided with various other arrangements of a content addressable memory (CAM).

While the present invention has been described with reference to the details of the embodiments of the invention shown in the drawing, these details are not intended to limit the scope of the invention as claimed in the appended claims.

1. Apparatus for implementing power saving in a content addressable memory (CAM) comprising:
a compare array generating match signals responsive to a match of said compare array and a key;
a data array including precharge circuitry and data output latches to capture a data output;
logic coupled to said compare array generating a hit signal and activating a wordline responsive to said match signals; said logic applying said wordline to access said data array and said data output latches of said data array capturing said data output;
said data array remains in an inactive state when a hit does not occur;
a clock gate coupled to said logic, said clock gate connected to said output latches and said precharge circuitry and applying clock signals to said output latches and said precharge circuitry of said data array when a hit occurs;
said clock gate gating off the clock signals to said output latches and said precharge circuitry of said data array when a hit does not occur; and
said precharge circuitry remains on and is not changed in said inactive state of said data array.

2-3. (canceled)

4. Apparatus for implementing power saving in a content addressable memory (CAM) as recited in claim 3 wherein a state of said output latches is not changed in said inactive state of said data array.

5. (canceled)

6. Apparatus for implementing power saving in a content addressable memory (CAM) as recited in claim 1 wherein said precharge circuitry applies precharge signals to read bitlines of said data array when a hit occurs.

7. Apparatus for implementing power saving in a content addressable memory (CAM) as recited in claim 6 wherein said precharge circuitry remains on and is not changed when a hit does not occur.

8. A method for implementing power saving in a content addressable memory (CAM) including a compare array for generating match signals responsive to a match of a compare array and a key; a data array including precharge circuitry and data output latches to capture a data output, and logic coupled to said compare array for generating a hit signal and activating a wordline responsive to said match signals, said logic applying said wordline to access said data array and said data output latches of said data array capturing said data output and said data array remains in an inactive state when a hit does not occur; said method comprising the steps of:
providing a clock gate coupled to said logic for receiving said hit signal, said clock gate being connected to said output latches and said precharge circuitry and used for:
applying clock signals to said output latches and said precharge circuitry of said data array when a hit occurs;
gating off said clock signals to said output latches and said precharge circuitry of said data array when a hit does not occur; and
said precharge circuitry remaining on and not being changed in said inactive state of said data array responsive to said clock signals being gated off.

9-10. (canceled)

11. A method for implementing power saving in a content addressable memory (CAM) as recited in claim 8 wherein a state of said output latches is not changed in said inactive state of said data array.

12. A method for implementing power saving in a content addressable memory (CAM) as recited in claim 8 wherein said precharge circuitry applies precharge signals to read bitlines of said data array when a hit occurs.

13. (canceled)
